(19) United States
(12) Patent Application Publication
(10) Pub. No.: US 2007/0102756 A1
(43) Pub. Date: May 10, 2007

(54) FinFET transistor fabricated in bulk semiconducting material

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/271,375

(22) Filed: Nov. 10, 2005

(51) Int. Cl. H01L 29/76

(52) U.S. Cl. 257/327

(57) ABSTRACT

A field effect transistor (FET) device structure and method for forming FETs for scaled semiconductor devices. Specifically, FinFET devices are fabricated from bulk semiconductor wafers, as opposed to silicon-on-insulator (SOI) or separation by implantation of oxygen (SIMOX) wafers, in a highly uniform and reproducible manner. The method facilitates formation of FinFET devices from readily-available bulk semiconductor substrates with improved and reproducible fin height control while providing isolation between source and drain regions of the FinFET device.

### TECHNICAL FIELD

The present invention relates generally to FET and MOSFET transistors, and more particularly the invention relates to field effect transistors having channel regions extending vertically from a supporting substrate between horizontally disposed source and drain regions.

### BACKGROUND ART

Metal-oxide-semiconductor field effect transistor (MOSFET) technology is a dominant electronic device technology in use today. Performance enhancement between generations of devices is generally achieved by reducing an overall size of the device, resulting in an enhancement in device speed. This size reduction is generally referred to as device scaling. As MOSFETs are scaled to channel lengths below about 100 nm, conventional MOSFETs suffer from several problems. In particular, interactions between the source and drain of the MOSFET degrade an ability of the gate to control whether the device is on or off. The degradation in control ability phenomenon is called a short-channel effect (SCE). Silicon-on-insulator (SOI) MOSFETs are formed with an insulator (usually, but not limited to, silicon dioxide or sapphire) below an active region of the device, unlike conventional bulk MOSFETs, which are formed directly on silicon substrates, and hence have silicon below all active regions. SOI is generally considered advantageous as it reduces unwanted coupling between the source and the drain of the MOSFET through the region below the channel. Other techniques, such as separation by implantation of oxygen (SIMOX) functions similarly to SOI. The reduction in coupling in SOI and SIMOX is often achieved by ensuring that all the silicon in the MOSFET channel region can be either inverted or depleted by the gate (called a fully depleted MOSFET). As device size is scaled, however, ensuring a fully depleted channel region becomes increasingly difficult, since the distance between the source and drain is reduced. The reduced distance results in an increased interaction with the channel thus reducing gate control and increasing short channel effects.

A double-gate MOSFET structure places a second gate in the device, such that there is a gate on either side of the channel. The double-gate allows gate control of the channel from both sides. Additionally, when the device is turned off using both gates, the off-state transistor current is reduced. An extension of the double-gate concept is a surround-gate or wraparound-gate concept, where the gate is placed such that it completely or almost-completely surrounds the channel, providing improved channel control. These surround-gate and wraparound-gate concepts are also formed on SOI or SIMOX and are referred to as FinFET devices due to the silicon-etched fin produced above the oxide/insulator level. Such a FinFET device is presented in U.S. Pat. No. 6,413,802, entitled “FinFET Transistor Structures Having a Double Gate Channel Extending Vertically from a Substrate and Methods of Manufacture,” issued to Hu et al.

Additional significant unsolved problems remain with the aforementioned electronic devices. For example, if a FET device, especially a CMOS device, is used as nonvolatile memory, a body contact needs to be made to the top layer of silicon, thus increasing the area of the device. In addition to the increased area required, the body contact problem has prevented the semiconductor industry from using FinFET devices for nonvolatile memory due to current processing complications in making the contact. To create the contact, an additional via needs to be formed followed by a typically multi-part fill process using tungsten and tantalum. On a typical 300 mm wafer currently used today, each of the tens or hundreds of millions of vias must fully clear and each metal contact must be fully formed to prevent degradation in device performance. U.S. Pat. No. 6,642,090 to Fried et al. entitled “Fin FET Devices from Bulk Semiconductor and Method for Forming Same” defines a process for forming a FinFET device on a semiconductor wafer by forming a fin from the semiconductor wafer wherein the fin includes a fin sidewall; exposing areas of the semiconductor wafer adjacent to the fin; damaging at least a portion of the semiconductor substrate areas adjacent to the fin; and oxidizing the semiconductor substrate such that silicon dioxide is formed in the damaged portion of the semiconductor substrate to a greater thickness than is formed on the fin sidewall. However, the Fried et al. method requires careful control of a silicon etch depth in the bulk wafer, a “damaging process” in areas of silicon surrounding the fin, oxidation of the damaged areas, and a fin oxidation process to thin the fin to a required level. Each of these processes require tremendous process control and are likely non-manufacturable in a production environment.

Therefore, what is needed is a method of forming a FinFET device in a bulk semiconducting material by a process that is reproducible and fully adaptable to high-volume semiconductor fabrication processes.

### SUMMARY

A field effect transistor (FET) device structure and method for forming FETs for scaled semiconductor devices is presented. Specifically, FinFET devices described are fabricated from bulk semiconductor wafers, as opposed to silicon-on-insulator (SOI) or separation by implantation of oxygen (SIMOX) wafers, in a highly uniform and reproducible manner. The method facilitates formation of FinFET devices from readily-available bulk semiconductor substrates with improved and reproducible fin height control while providing isolation between source and drain regions of the FinFET device.

An exemplary FET device structure includes a fin fabricated from a bulk semiconducting material, for example, bulk silicon; a gate region comprised of a semiconducting material, with the gate region overlying a first portion of the fin and being doped with a majority carrier of a first type; a drain region formed on a second portion of the fin, the drain region being located on a first side of the gate region, the drain region being doped with a majority carrier of a second type; and a source region formed on a third portion of the fin, the source region being distal to the drain region and located on a second side of the gate region, the source region being doped with the majority carrier of the second type.

An exemplary method for producing the FinFET structure includes forming a fin in a bulk semiconducting material. The bulk semiconducting material may be, for example, silicon. A first dielectric layer is formed on the silicon substrate prior to forming the fin. The first dielectric layer is comprised of a first type of dielectric material. A second dielectric layer is then formed over the substrate, also prior to forming the fin where the second dielectric layer is comprised of a second type of dielectric material. An additional dielectric material is formed on sidewalls of the fin after the fin has been formed and a space on either side of the fin is filled with a non-conducting material. An uppermost portion of the non-conducting material is etched-back such that a given height of the fin is exposed above the etched-back portion of the non-conducting material. A thin gate oxide is formed over the fin and a semiconducting gate region is subsequently formed over the thin oxide. The semiconducting gate region is doped with a first type of majority carrier. Portions of the fin not covered by the semiconducting gate region may be doped with a dopant having a second type of majority carrier.

### BRIEF DESCRIPTION OF THE DRAWINGS

FIGS. 1A-1K show various cross-sectional stages in an exemplary process flow for producing a MOS transistor with surrounded gate.

### DETAILED DESCRIPTION

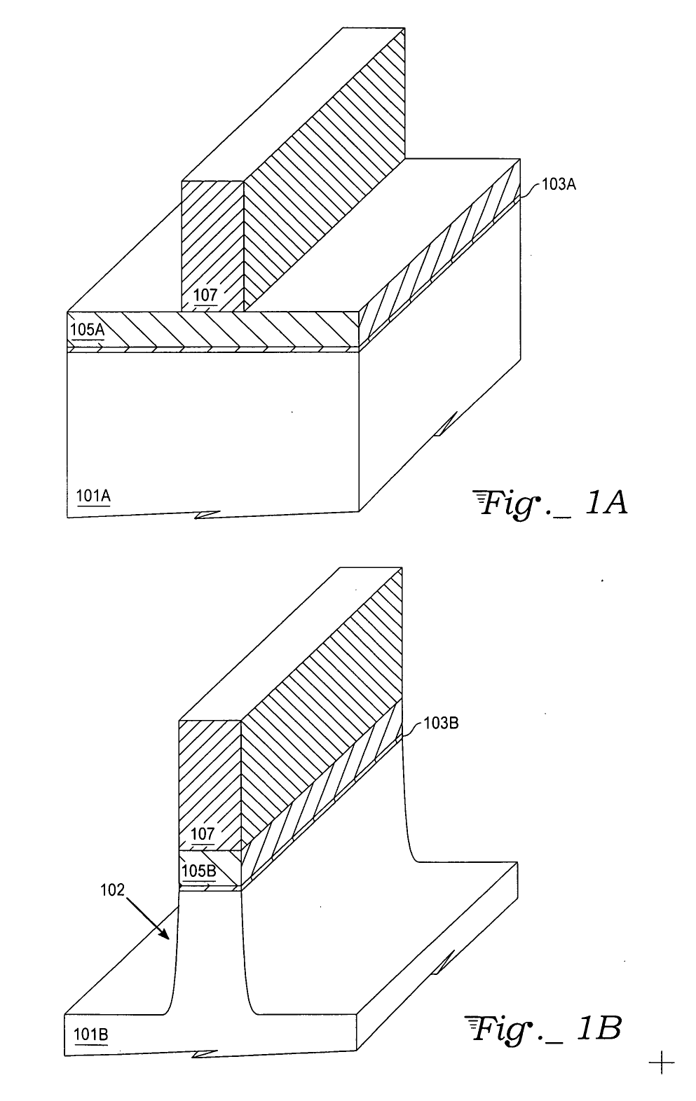

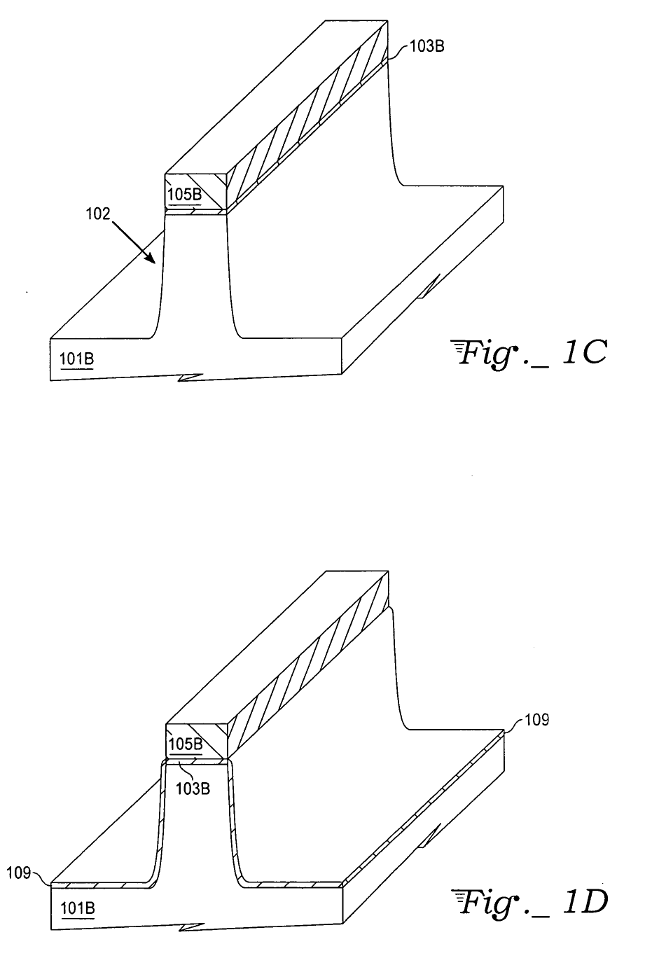

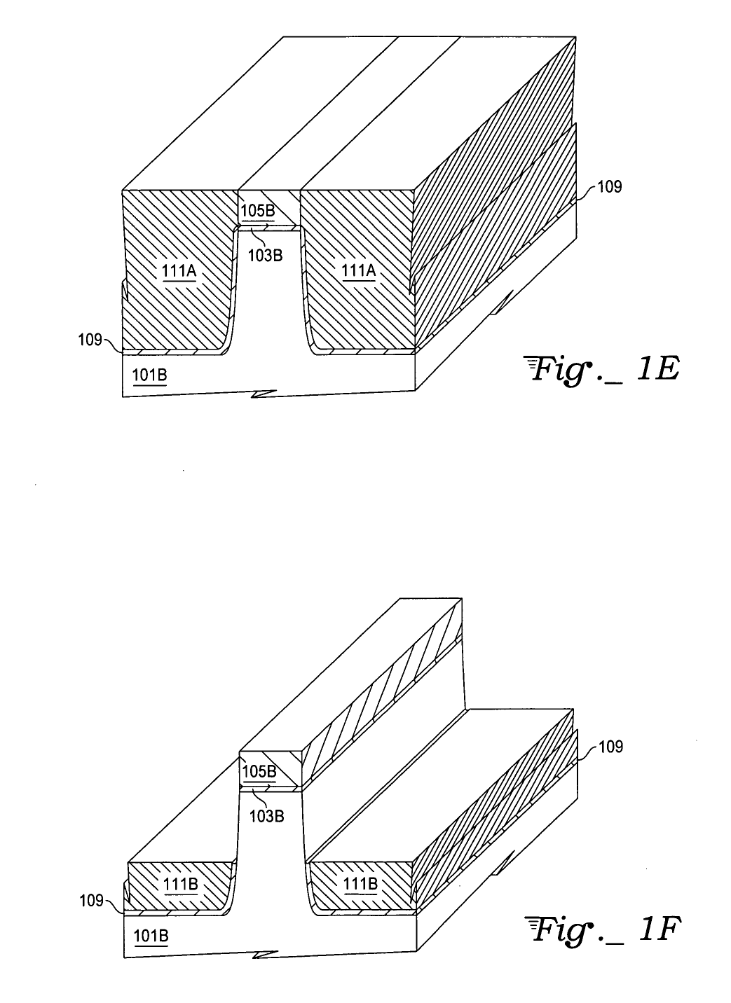

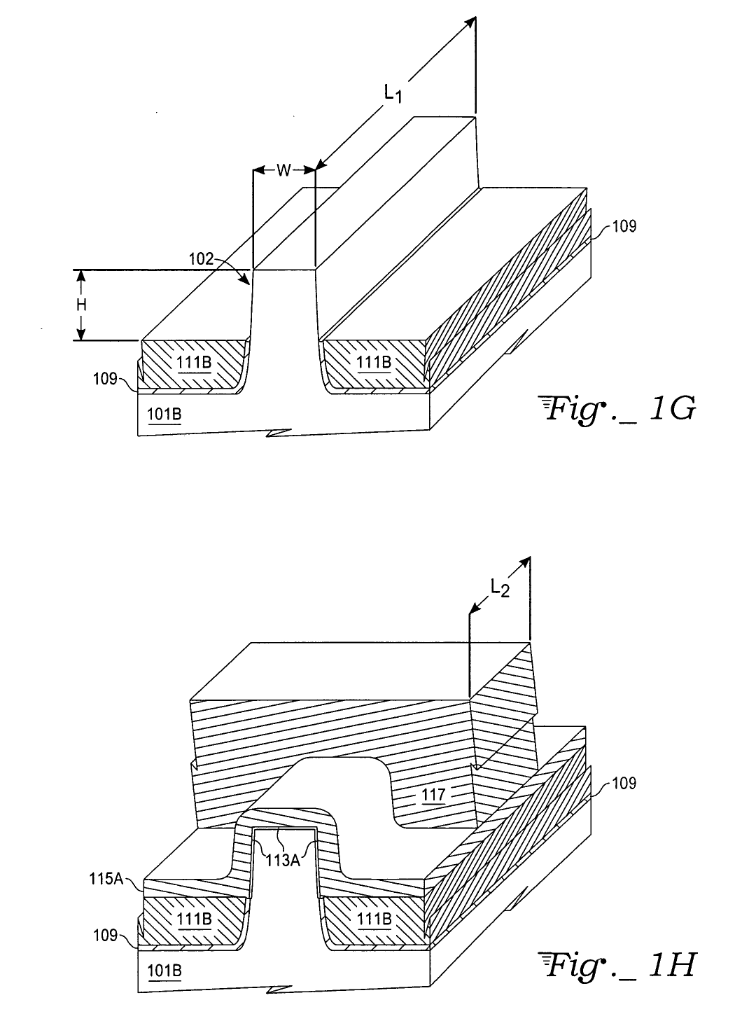

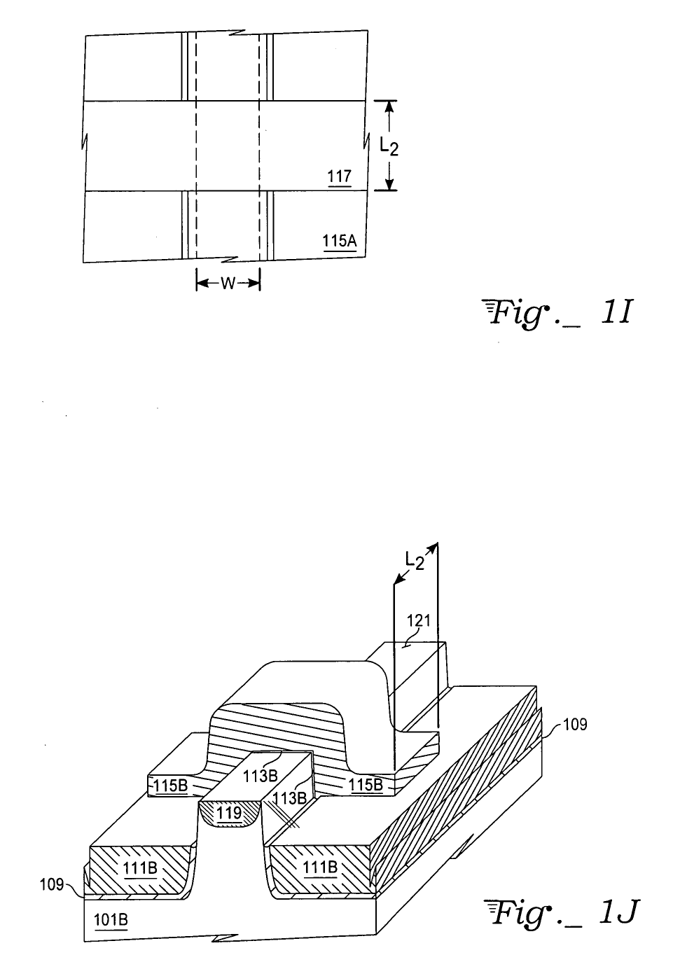

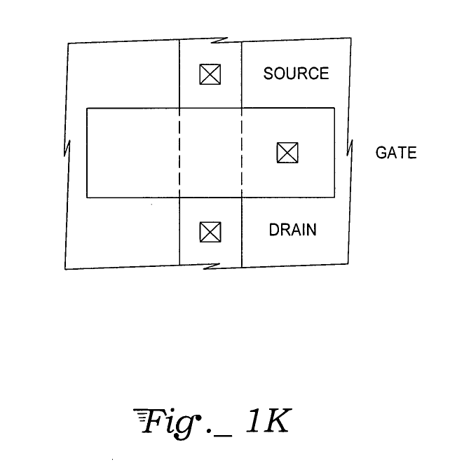

With reference to FIG. 1A, a substrate 101A has a thin silicon dioxide layer 103A, a thicker silicon nitride layer 105A, and a patterned photoresist mask layer 107. In a specific exemplary embodiment, the substrate 101A is be a silicon wafer. However, a skilled artisan will recognize that other semiconductor materials may be used instead of silicon for the substrate 101A. Other semiconductor materials include, for example, elemental semiconductors such as germanium, compound semiconductors such as group III-V, and II-VI materials, and semiconducting alloys. If elemental semiconductors other than silicon, or compound semiconductors are employed, an atomic layer deposition (ALD) process may be employed for producing thin, high quality oxide layers.

The silicon dioxide layer 103A is a pad oxide to prevent thermally-induced stresses from developing between particular dissimilar materials, such as between silicon and the silicon nitride layer 105A. The silicon dioxide layer 103A may be thermally grown or deposited. The silicon nitride layer 105A is then formed over the silicon dioxide layer 103A by, for example, chemical vapor deposition (CVD). In a specific exemplary embodiment, the silicon dioxide layer 105A is between 50 Å and 100 Å while the silicon nitride layer 105A is between 400 Å and 1000 Å. The patterned photoresist mask layer 107 may be repeated a number of times and disposed laterally over a surface of the substrate 101A to fabricate multiple surrounded-gate devices. For clarity, only one such device will be shown and described herein.

FIG. 1B indicates a fin area 102 being fabricated from an etched substrate 101B. To form the fin area 102, the photoresist mask layer 107 defines an area for which underlying areas will not be etched. These layers (i.e., the silicon nitride layer 105A and silicon dioxide layer 103A) are etched in accordance with methods well-known in the semiconductor arts. For example, depending upon a chemical composition of a given layer, etching may be accomplished through various wet etch (e.g., in hydrofluoric acid, such as contained in a standard buffered oxide etch, or orthophosphoric acid) or dry-etch techniques (e.g., reactive-ion etch (RIE)). Once an etched silicon nitride layer 105B and an etched silicon dioxide layer 103B are formed, the underlying substrate 101A is etched, defining the etched substrate 101B. For example, dry-etch techniques, such as a reactive ion etch (RIE), may be employed.

A sidewall slope of the fin area 102 may be controlled through a choice of the chemistry used in a dry-etch recipe and/or through a choice of the substrate 101A if a monocrystalline semiconductor is used. A skilled artisan will recognize that a sidewall of the fin area 102 may be fabricated in any appropriate crystallographic plane. The appropriate plane may be selected to enhance device characteristics such as, for example, electron mobility.

After producing the fin area 102, the photoresist mask layer 107 is removed (FIG. 1C) and a gate oxide layer 109 is thermally grown (FIG. 1D) after an appropriate pre-oxidation clean. In other exemplary embodiments, the gate oxide layer may be conformally deposited by CVD. Thinner layers of gate oxide (e.g., 10 Å to 30 Å) may be deposited by techniques such as atomic layer deposition (ALD), or other advanced technology.

In FIG. 1E, a dielectric fill layer 111A is deposited over the gate oxide layer 109. The dielectric fill process may be similar to shallow-trench isolation (STI) type fills known in the art, for example, a high density plasma (HDP) oxide fill. The dielectric fill layer 111A may be comprised of any insulative material such as silicon dioxide, or any of a number of other appropriate materials deposited or otherwise formed over the gate oxide layer 109. The dielectric fill layer 111A may be brought to a level roughly coplanar with an uppermost part of the etched silicon nitride layer 105B through, for example, chemical mechanical planarization (CMP).

The dielectric fill layer 111A is then etched, producing an etched dielectric fill layer 111B (FIG. 1F). A high-selectivity etchant prevents the etched silicon nitride layer 105B from being substantially etched away during the dielectric fill layer 111A etch. Further, if the gate oxide layer 109 is comprised of thermally grown silicon dioxide, the gate oxide layer 109 will etch more slowly than an HDP layer used for the dielectric fill layer 111A (i.e., an etch rate of thermal oxide is lower than HDP oxide as HDP is less dense). If an exposed portion of the gate oxide layer 109 (i.e., the portion above the etched dielectric fill layer 111B) is not etched completely, it will be removed prior to a final gate oxidation step described infra.

With reference to FIG. 1G, the etched silicon nitride layer 105B, the etched silicon dioxide layer 103B, and exposed portions of the gate oxide layer 109 are substantially etched away using techniques known to a skilled artisan. An exposed section of the fin area 102 defines an active region of the FET device. The active region has a given height, H, length, L₁, and width, W. In a specific exemplary embodiment, the active region height, H, is approximately 100 nm to 500 nm. The width of the active region, W, is approximately 100 nm or less and the length, L₁, is dependent on a number of factors such as device design rules and gate widths.

A thermal oxidation, ALD, or high-k oxide deposition process forms a final thin gate oxide 113A (FIG. 1H) over the active region. In a specific exemplary embodiment, the final thin gate oxide is grown or deposited to a thickness of approximately 10 Å to 30 Å. A polysilicon layer 115A is then conformally deposited (FIG. 1H). The polysilicon layer 115A will form a gate region, described infra. A patterned second photoresist layer 117 is formed and patterned to define the gate; the gate having a width commensurate with a length, L₂, of the patterned second photoresist layer 117. FIG. 1I is a plan view of the FET device and thus provides clarity in understanding a layout of the device after the second photoresist layer 117 is added. The hidden section is an uppermost portion of the channel active region of FIG. 1G.

With reference to FIG. 1J, a selective etch process (either wet-etch or dry-etch) is used to fully define a gate region 115B of the device. Generally, a high selectivity to either silicon or silicon dioxide is accomplished using an appropriate chemistry. Doped areas are added (e.g., by diffusion or implantation) to define a drain contact region 119 and a source contact region 121 (or LDD structure) of the device by well-established practice. The patterned second photoresist layer 117 is then removed. FIG. 1K provides a plan view-showing source, gate, and drain contact areas of a completed FinFET device fabricated according to exemplary embodiments described herein. Subsequent steps for completion of the FinFET device follow conventional CMOS fabrication processes.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that other types of semiconducting and insulating materials other than those listed may be employed. Additional particular process fabrication and deposition techniques, such as low pressure chemical vapor deposition (LPCVD), ultra-high vacuum CVD (UHCVD), and low pressure tetra-ethoxysilane (LPTEOS) may be readily employed for various layers and still be within the scope of the present invention. Although the exemplary embodiments describe a second gate oxide being formed, a single gate oxide may also be used provided that subsequent process steps do not etch through the gate oxide. The substrate may also be comprised of a non-semiconducting material, for example, a quartz pellicle with a deposited and doped polysilicon layer. (In this embodiment, the doped polysilicon layer becomes the bulk semiconductor.) Additionally, although the exemplary embodiments are described in terms of MOS integrated circuit devices, a person of ordinary skill in the art will recognize that other fabrication techniques, such as bipolar or BiCMOS techniques, may readily be employed as well. The specification and drawings are, accordingly, to be regarded in an illustrative rather than a restrictive sense.

What is claimed is:

1. A method for forming an electronic device, the method comprising:
providing a substrate;
forming a fin on the substrate, the fin being produced in a bulk semiconducting material of the substrate, the fin having a given width;
filling a space on either side of the fin with a non-conducting material;
etching back an uppermost portion of the non-conducting material such that a given height of the fin is exposed above the etched-back portion of the non-conducting material;
forming a thin oxide over the fin; and
forming a semiconducting gate region over the thin oxide, the semiconducting gate region covering a channel, the channel being doped with a first type of majority carrier.

2. The method of claim 1, further comprising doping portions of the fin not covered by the semiconducting gate region, the dopant having a second type of majority carrier.

3. The method of claim 1 wherein the fin is formed from a substrate being comprised of bulk silicon.

4. The method of claim 3 wherein an orientation of the bulk silicon is chosen so as to enhance electrical performance of the device.

5. The method of claim 1 wherein the fin is formed from a substrate comprised of a strain-compensated semiconducting material.

6. The method of claim 1 wherein the width of the fin is formed to be less than 100 nm.

7. The method of claim 1 wherein the height of the fin is formed to be in a range of approximately 100 nm to 500 nm.

8. The method of claim 1, further comprising:
forming a first dielectric layer on the substrate prior to forming the fin, the first dielectric layer being comprised of a first type of dielectric material;
forming a second dielectric layer over the substrate prior to forming the fin, the second dielectric layer being comprised of a second type of dielectric material; and
forming a dielectric material on sidewalls of the fin after the fin has been formed.

9. The method of claim 8 wherein a planarization step of the non-conducting material occurs prior to etching back an uppermost portion of the non-conducting material and is accomplished by chemically mechanically planarizing the material.

10. An electronic device, comprising:
a fin fabricated from a bulk semiconducting material;
a gate region comprised of a semiconducting material, the gate region overlying a first portion of the fin, the first portion of the fin being doped with a majority carrier of a first type; and
a drain region formed on a second portion of the fin, the drain region being located on a first side of the gate region, the drain region being doped with a majority carrier of a second type.

11. The electronic device of claim 10 further comprising a source region formed on a third portion of the fin, the source region being distal to the drain region and located on a second side of the gate region, the source region being doped with the majority carrier of the second type.

12. The device of claim 10 wherein the bulk semiconducting material is silicon.

13. The method of claim 12 wherein a sidewall of the fin is fabricated in any appropriate crystallographic plane of the bulk silicon.

14. An electronic device, comprising:
a fin on a substrate, the substrate comprising a bulk semiconducting material, the fin being fabricated by steps including:
(i) producing the fin in the bulk semiconducting material of the substrate, the fin having a given width;
(ii) filling a space on either side of the fin with a non-conducting material;
(iii) etching back an uppermost portion of the non-conducting material such that a given height of the fin is exposed above the etched-back portion of the non-conducting material; and
(iv) forming a thin oxide over the fin;
a gate region comprised of a semiconducting material, the gate region overlying a first portion of the fin, the first portion of the fin being doped with a majority carrier of a first type;
a drain region formed on a second portion of the fin, the drain region being located on a first side of the gate region, the drain region being doped with a majority carrier of a second type; and
a source region formed on a third portion of the fin, the source region being distal to the drain region and located on a second side of the gate region, the source region being doped with the majority carrier of the second type.

15. The device of claim 14 wherein the bulk semiconducting material is silicon.

16. The device of claim 15 wherein a sidewall of the fin is fabricated in any appropriate crystallographic plane of the bulk silicon.

17. The device of claim 14 wherein the bulk semiconducting material is comprised of a strain-compensated compound semiconductor.

18. A method for forming an electronic device, the method comprising:
providing a bulk silicon substrate;
forming a fin from the silicon substrate, the fin having a given width;
forming a first dielectric layer on the silicon substrate prior to forming the fin, the first dielectric layer being comprised of a first type of dielectric material;
forming a second dielectric layer over the substrate prior to forming the fin, the second dielectric layer being comprised of a second type of dielectric material;
forming a dielectric material on sidewalls of the fin after the fin has been formed;
filling a space on either side of the fin with a non-conducting material;
etching back an uppermost portion of the non-conducting material such that a given height of the fin is exposed above the etched-back portion of the non-conducting material;
forming a thin oxide over the fin;
forming a semiconducting gate region over the thin oxide, the semiconducting gate region covering a channel, the channel being doped with a first type of majority carrier; and
doping portions of the fin not covered by the semiconducting gate region, the dopant having a second type of majority carrier.

19. The method of claim 18 wherein the first dielectric layer is comprised of silicon dioxide.

20. The method of claim 18 wherein the second dielectric layer is comprised of silicon nitride.

21. The method of claim 18 wherein a sidewall of the fin is fabricated in any appropriate crystallographic plane of the bulk silicon.

22. The method of claim 18 wherein an orientation of the bulk silicon is chosen so as to enhance electrical performance of the device.

23. The method of claim 18 wherein the width of the fin is formed to be less than 100 nm.

24. The method of claim 18 wherein the height of the fin is formed to be in a range of approximately 100 nm to 500 nm.

25. A method for forming an electronic device, the method comprising:
providing a substrate;
forming a fin on the substrate, the fin being produced in a bulk semiconducting material of the substrate, the fin having a given width;
filling a space on either side of the fin with a non-conducting material until a given height of the fin is exposed above the substrate;
forming a thin oxide over the fin;
forming a semiconducting gate region over the thin oxide, the semiconducting gate region covering a channel, the channel being doped with a first type of majority carrier; and
doping portions of the fin not covered by the semiconducting gate region, the dopant having a second type of majority carrier.

26. The method of claim 25 wherein the width of the fin is formed to be less than 100 nm.

27. The method of claim 25 wherein the height of the fin is formed to be in a range of approximately 100 nm to 500 nm.

28. The method of claim 25, further comprising:
forming a first dielectric layer on the substrate prior to forming the fin, the first dielectric layer being comprised of a first type of dielectric material;
forming a second dielectric layer over the substrate prior to forming the fin, the second dielectric layer being comprised of a second type of dielectric material; and
forming a dielectric material on sidewalls of the fin after the fin has been formed.

29. An electronic device, comprising:
a fin on a substrate, the substrate comprising a bulk semiconducting material, the fin being fabricated by steps including:
(i) producing the fin in the bulk semiconducting material of the substrate, the fin having a given width;
(ii) filling a space on either side of the fin with a non-conducting material until a given height of the fin is exposed above the substrate; and
(iii) forming a thin oxide over the fin;
a gate region comprised of a semiconducting material, the gate region overlying a first portion of the fin, the first portion of the fin being doped with a majority carrier of a first type; and
a drain region formed on a second portion of the fin, the drain region being located on a first side of the gate region, the drain region being doped with a majority carrier of a second type.

30. The device of claim 29, further comprising a source region formed on a third portion of the fin, the source region being distal to the drain region and located on a second side of the gate region, the source region being doped with the majority carrier of the second type.

31. The device of claim 29 wherein the bulk semiconducting material is silicon.

32. The device of claim 31 wherein a sidewall of the fin is fabricated in any appropriate crystallographic plane of the bulk silicon.
